(19) United States
(12) Patent Application Publication
(10) Pub. No.: US 2013/0277845 A1
(43) Pub. Date: Oct. 24, 2013

(54) STRUCTURE OF BACKSIDE COPPER METALLIZATION FOR SEMICONDUCTOR DEVICES AND A FABRICATION METHOD THEREOF

(71) Applicants: Jason CHEN, Tao Yuan Shien (TW); Chang-Hwang HUA, Tao Yuan Shien (TW); Wen CHU, Tao Yuan Shien (TW)

(72) Inventors: Jason CHEN, Tao Yuan Shien (TW); Chang-Hwang HUA, Tao Yuan Shien (TW); Wen CHU, Tao Yuan Shien (TW)

(73) Assignee: WIN SEMICONDUCTORS CORP., Tao Yuan Shien (TW)

(21) Appl. No.: 13/555,793

(22) Filed: Jul. 23, 2012

(30) Foreign Application Priority Data
Apr. 18, 2012 (TW) 101113779

(51) Int. Cl. H01L 23/48; H01L 21/283

(52) U.S. Cl. 257/762; 438/650; 438/642; 257/E23.01; 257/E21.159

(57) ABSTRACT

An improved structure of backside copper metallization for semiconductor devices and a fabrication method thereof, in which the improved structure comprises sequentially from top to bottom an active layer, a substrate, a backside metal seed layer, at least one thermal expansion buffer layer, a backside metal layer, and at least one oxidation resistant layer, in which the backside metal seed layer is formed of Pd, and the thermal expansion coefficient of the thermal expansion buffer layer is in the range between the thermal expansion coefficients of the backside metal seed layer and of the backside metal layer. The semiconductor chip using the structure provided by the present invention can sustain high-temperature operations.

### FIELD OF THE INVENTION

The present invention relates to an improved structure of the backside copper metallization for semiconductor devices and a fabrication method thereof, and particularly to semiconductor devices using copper layer as the backside metal layer, Pd layer as the backside metal seed layer, and inserting a thermal expansion buffer layer in between for sustaining high-temperature operations.

### BACKGROUND OF THE INVENTION

The fabrication processes of semiconductor devices usually include a backside metallization process, which is essential for heat dissipation, the device grounding, as well as improving the die strength. FIG. 1 is a schematic showing the backside copper structure of semiconductor devices according to conventional technologies, in which the structure sequentially comprises a substrate 101, a diffusion barrier layer 105, a stress-reducing metal layer 107, a backside metal layer 109, and an oxidation resistant layer 111. The diffusion barrier layer 105 is formed below the substrate 101. The diffusion barrier layer 105 is made of TaN, which is used mainly for preventing device damages caused by the diffusion of other metal atoms into the substrate 101. The stress-reducing metal layer 107 is formed below the diffusion barrier layer 105. The stress-reducing metal layer 107 is made of Au, which can prevent metal peeling off from the underneath structure caused by the mismatched thermal expansions/contractions in different material layers. The backside metal layer 109 is made of Cu. The backside metal layer 109 should be thick enough to support the substrate 101 for sustaining the large stress during packaging processes. A thick backside metal layer is also helpful for device heat dissipation. The oxidation resistant layer 111 is made of Au, which can prevent the oxidation of the backside metal layer 109.

However, choosing TaN for the diffusion barrier layer, Au for the stress-reducing metal layer, and Cu for the backside metal layer is not adequate for semiconductor devices that demanded for high-temperature operations. The heat dissipation and thermal resistance of semiconductor devices are important topics nowadays. A semiconductor device may be damaged by over-heating when its thermal resistance is not good enough, particularly when backside via holes with large depth to width aspect ratios are presented in the semiconductor devices. Under high temperature operations, the three-layer structure would crack or peel off, leading to poor grounding and device damages.

In view of these facts and for overcoming the drawback stated above, the present invention provides an improved structure of the backside copper metallization a fabrication method thereof for semiconductor devices that can sustain high temperature operations. The improved structure and the fabrication method thereof according to the present invention can also improve the thermal conductivity of the semiconductor chip with a lower production cost.

### SUMMARY OF THE INVENTION

The main object of the present invention is to provide an improved structure of the backside copper metallization a fabrication method thereof for semiconductor devices that can sustain high temperature operations.

To reach the objects stated above, the present invention provides an improved structure of the backside copper metallization for semiconductor devices, which comprises from top to bottom an active layer, a substrate, a backside metal seed layer, at least one thermal expansion buffer layer, and a backside metal layer; wherein the active layer includes at least one integrated circuit; wherein the material for the backside metal seed layer is Pd; wherein the material for the backside metal layer is Cu; and wherein the thermal expansion coefficient of the thermal expansion buffer layer is in the range between the thermal expansion coefficients of the backside metal seed layer and of the backside metal layer.

In implementation, the previously described thermal expansion buffer layer is formed of Ni, Ag, or Ni alloys.

In implementation, the thickness of the thermal expansion buffer layer is larger than 0.01 μm and smaller than 5 μm.

In implementation, at least one oxidation resistant layer can be further included in the structure below the backside metal layer.

In implementation, the oxidation resistant layer is made of Ni, Au, Pd, Ni—Au alloys, Ni—Pd alloys, Pd—Au alloys, or Ni—V alloys.

The present invention further provides a fabrication method of an improved structure of the backside copper metallization for semiconductor devices, which includes the following steps:

forming an active layer on the front side of a substrate, which comprises at least one integrated circuit;

fabricating requested number of via holes on the backside of the substrate by using photolithography and etching technologies;

depositing a backside metal seed layer covering on the backside of the substrate and on the interior surface of said via holes, wherein the backside metal seed layer is made of Pd;

depositing at least one thermal expansion buffer layer covering on the backside metal seed layer; and

depositing a backside metal layer covering on the thermal expansion buffer layer, and the material for said backside metal layer is Cu,

in which the thermal expansion coefficient of the thermal expansion buffer layer is in the range between the thermal expansion coefficients of the backside metal seed layer and of the backside metal layer.

In implementation, the previously described thermal expansion buffer layer is formed of Ni, Ag, or Ni alloys.

In implementation, the thickness of the thermal expansion buffer layer is larger than 0.01 μm and smaller than 5 μm.

In implementation, the following steps can be further included in the fabrication method: defining at least one street on the backside metal layer by photolithograph; then etching the backside metal layer and terminating the etching process at the thermal expansion buffer layer to form streets on the backside metal layer; finally depositing at least one oxidation resistant layer covering on the backside metal layer and the streets to prevent metal oxidations.

In implementation, the oxidation resistant layer is made of Ni, Au, Pd, Ni—Au alloys, Ni—Pd alloys, Pd—Au alloys, or Ni—V alloys.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of the structure of backside copper metallization for semiconductor devices according to a previous technology.

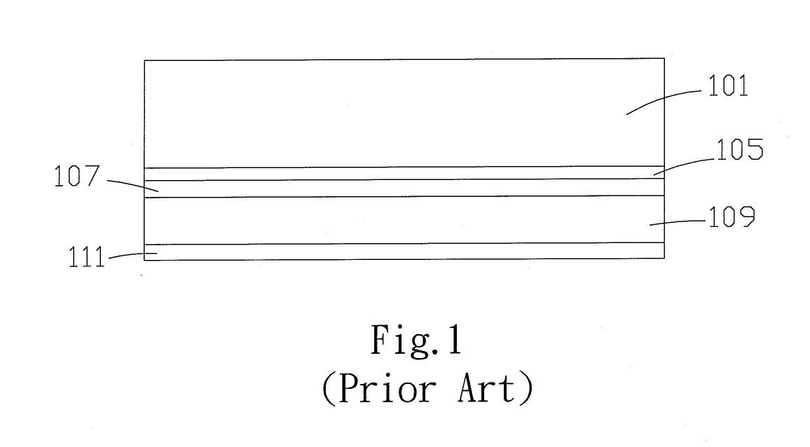

FIG. 2A is a schematic showing the cross-sectional view of the structure of semiconductor devices according to the present invention before the backside copper metallization.

FIG. 2B is a schematic showing the cross-sectional view of the structure of backside copper metallization of semiconductor devices according to the present invention.

FIG. 2C is a schematic showing the cross-sectional view of the structure of backside copper metallization for semiconductor devices according to the present invention after forming streets by etching the backside metal layer.

FIG. 2D is a schematic showing the cross-sectional view of the structure of backside copper metallization for semiconductor devices according to the present invention after depositing an oxidation resistant layer.

FIG. 3 is a flow chart of the fabrication method of the improved structure of backside copper metallization for semiconductor devices provided by the present invention.

### DETAILED DESCRIPTIONS OF PREFERRED EMBODIMENTS

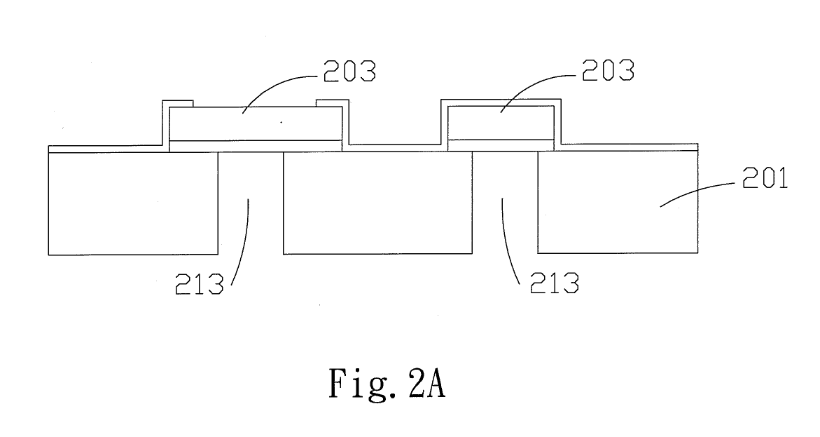

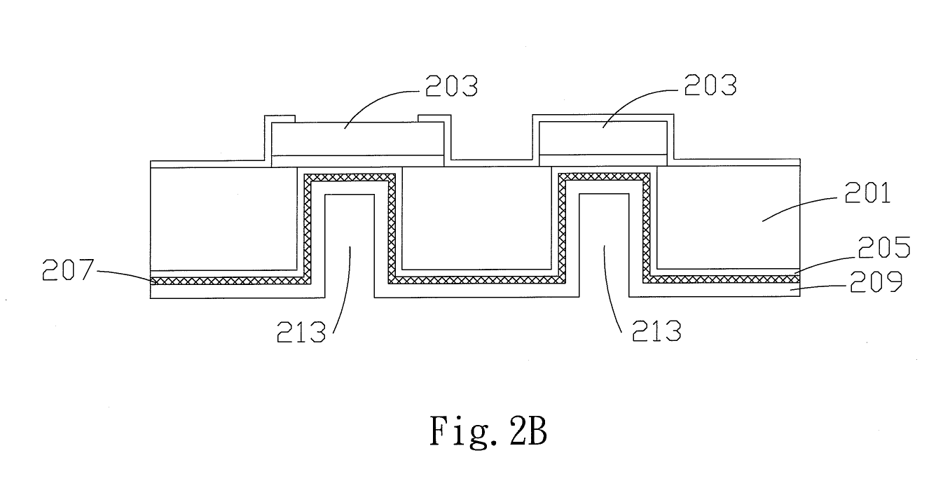

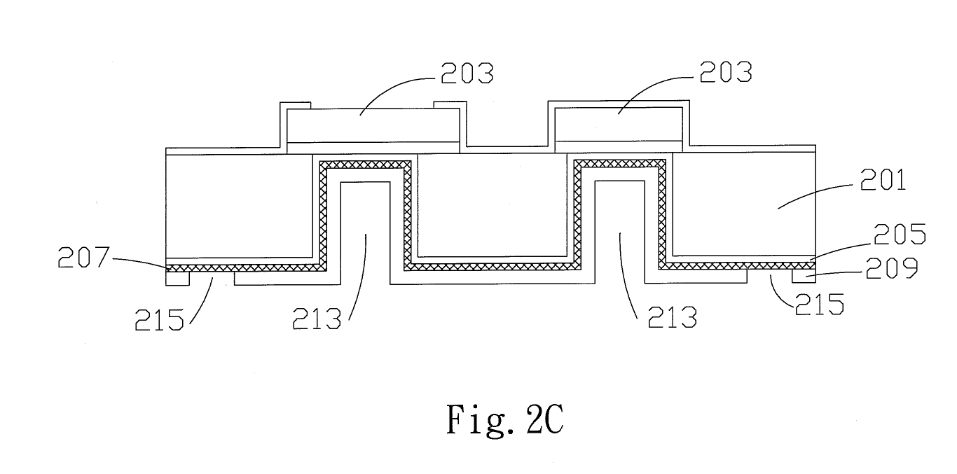

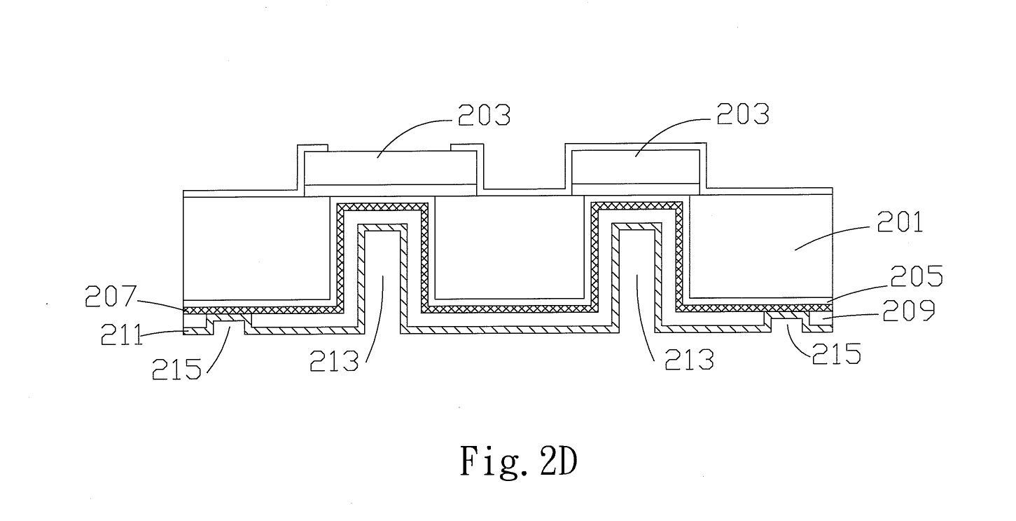

FIG. 2A is a schematic showing the cross-sectional view of the structure of semiconductor devices according to the present invention before the backside copper metallization, which comprises a substrate 201, which is formed preferably of semiconductor materials, such as GaAs, InP, GaN, SiC, etc. An active layer 203 is disposed on the front side of the substrate 201, and the active layer 203 includes at least one integrated circuit. The integrated circuit in the active layer 203 needs groundings. Therefore a requested number of backside via holes 213 are formed on the backside of the substrate 201 by using photolithography and etching technologies. The grounding points of the integrated circuit in the active layer 203 can be connected to a remote grounding pad through the backside via holes 213.

FIG. 2B is a cross-sectional view of the structure of backside copper metallization for semiconductor devices according to the present invention. The structure is formed by sequentially depositing a backside metal seed layer 205, at least a thermal expansion buffer layer 207, and a backside metal layer 209 on the backside of the substrate 201, in which the backside metal seed layer 205 covers the backside of the substrate 201 and the interior surface of the via holes 213; the thermal expansion buffer layer 207 is formed below the backside metal seed layer 205; and the backside metal layer 209 is formed below the thermal expansion buffer layer 207. The material for the backside metal seed layer is Pd, which can act as a diffusion barrier, preventing the diffusion of other metallic materials into the substrate 201 from below. Besides, using Pd as the material for the backside metal seed layer can also improve the adhesion to the substrate 201. The material for the backside metal layer 209 is Cu. On the other hand, the thermal expansion coefficient of the material for the thermal expansion buffer layer 207 should be in the range between the thermal expansion coefficients of the backside metal seed layer 205 and of the backside metal layer 209. The preferable materials for the thermal expansion buffer layer 207 are Ni, Ag, or Ni alloys. As a preferable embodiment, by using Pd as the backside metal seed layer 205, using Ni, Ag, or Ni alloys as the thermal expansion buffer layer 207, and using Cu as the backside metal layer 209, the fabricated devices can sustain higher temperature operations. No metal peeling or poor device grounding was found in devices after high-temperature tests, indicating that the device reliability can be significantly improved.

FIG. 2C is a schematic showing the cross-sectional view of the structure of backside copper metallization for semiconductor devices according to the present invention with streets on the backside metal layer. The structure is formed by first defining at least a street 215 on the backside metal layer 209 by photolithograph, and then etching the backside metal layer 209 and terminating the etching process at the thermal expansion buffer layer 207. The streets 215 on the backside metal layer 209 are thus formed.

FIG. 2D is a schematic showing the cross-sectional view of the structure of backside copper metallization for semiconductor devices according to the present invention with an oxidation resistant layer. The structure is formed by depositing at least one oxidation resistant layer 211 below the backside metal layer 209 after fabricating the streets 215 on the backside metal layer 209. The backside metal layer 209 and the streets 215 are thus covered with the oxidation resistant layer 211 and thereby preventing the oxidation of the backside metal layer 209. The oxidation resistant layer 211 is made preferably of Ni, Au, Pd, Ni—Au alloys, Ni—Pd alloys, Pd—Au alloys, or Ni—V alloys.

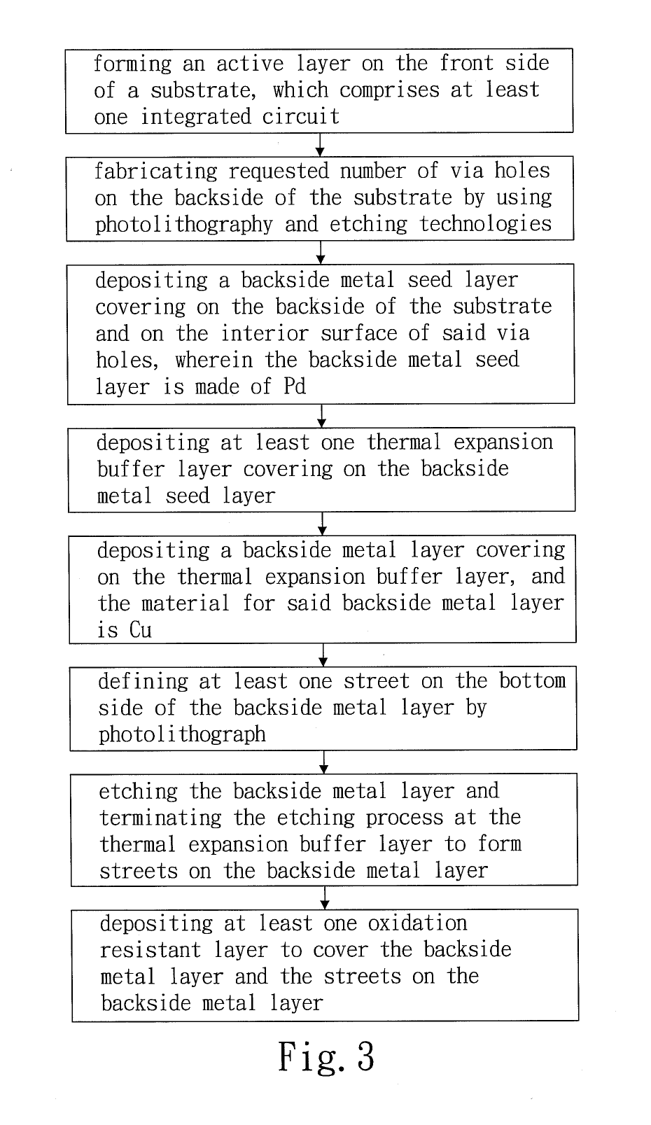

FIG. 3 is a flow chart of the fabrication method of the improved structure of backside copper metallization for semiconductor devices provided by the present invention. As shown in the figure, the previously described fabrication method of the improved structure of backside copper metallization for semiconductor devices includes the following steps:

forming an active layer on the front side of a substrate, which comprises at least one integrated circuit;

fabricating requested number of via holes on the backside of the substrate by using photolithography and etching technologies;

depositing a backside metal seed layer on the backside of the substrate covering on the backside of the substrate and the interior surface of the via holes, in which the backside metal seed layer is made of Pd ;

depositing at least one thermal expansion buffer layer covering on the backside metal seed layer;

depositing a backside metal layer covering on the thermal expansion buffer layer, in which the material for said backside metal layer is Cu;

wherein the thermal expansion coefficient of the thermal expansion buffer layer is in the range between the thermal expansion coefficients of the backside metal seed layer and of the backside metal layer.

Furthermore, as shown in FIG. 3, the previously described fabrication method can further include the following steps:

defining at least one street on the bottom side of the backside metal layer by photolithograph;

etching the backside metal layer and terminating the etching process at the thermal expansion buffer layer to form streets on the backside metal layer; and

depositing at least one oxidation resistant layer to cover the backside metal layer and the streets on the backside metal layer.

To sum up, by using the three-layer structure comprising the backside metal seed layer 205, the thermal expansion buffer layer 207, and the backside metal layer 209 provided by the present invention, in combination with the choice of the material for the three-layer structure, the temperature resistance of such a three-layer structure is increased. No metal peeling or poor grounding was found in devices after high-temperature tests, indicating that the device reliability has been improved. The present invention indeed can get its anticipatory object, and provide fabrication processes that can improve the device reliability.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

1. An improved structure of backside copper metallization for semiconductor devices comprising:
a substrate;
an active layer formed on the front side of said substrate comprising at least one integrated circuit;
a backside metal seed layer formed on the backside of said substrate and made of Pd;
at least one thermal expansion buffer layer formed below said backside metal seed layer; and
a backside metal layer formed below said thermal resistant layer and made of Cu,
wherein the thermal expansion coefficient of said thermal expansion buffer layer is in the range between the thermal expansion coefficients of said backside metal seed layer and of said backside metal layer.

2. The improved structure of backside copper metallization for semiconductor devices according to claim 1, wherein said thermal expansion buffer layer is made of Ni, Ag, or Ni alloys.

3. The improved structure of backside copper metallization for semiconductor devices according to claim 1, wherein the thickness of said thermal expansion buffer layer is larger than 0.01 μm and smaller than 5 μm.

4. The improved structure of backside copper metallization for semiconductor devices according to claim 1, wherein at least an oxidation resistant layer is further included below said backside metal layer.

5. The improved structure of backside copper metallization for semiconductor devices according to claim 4, wherein said oxidation resistant layer is made of Ni, Au, Pd, Ni—Au alloys, Ni—Pd alloys, Pd—Au alloys, or Ni—V alloys.

6. A fabrication method of an improved structure of backside copper metallization for semiconductor devices comprising the following steps:
forming an active layer on the front side of a substrate, wherein said active layer comprises at least one integrated circuit;
fabricating requested number of via holes on the backside of said substrate by using photolithography and etching technologies;
depositing a backside metal seed layer on the backside of said substrate to cover the backside of said substrate and the interior surface of said via holes, wherein said backside metal seed layer is made of Pd;
depositing at least one thermal expansion buffer layer to cover said backside metal seed layer; and
depositing a backside metal layer to cover said thermal expansion buffer layer, and the material for said backside metal layer is Cu,
wherein the range of the thermal expansion coefficient of said thermal expansion buffer layer is between the thermal expansion coefficients of said backside metal seed layer and of said backside metal layer.

7. The fabrication method according to claim 6, wherein said thermal expansion buffer layer is made of Ni, Ag, or Ni alloys.

8. The fabrication method according to claim 6, wherein the thickness of said thermal expansion buffer layer is larger than 0.01 μm and smaller than 5 μm.

9. The fabrication method according to claim 6 further including the following steps:
defining at least one street on said backside metal layer by photolithograph;
etching said backside metal layer and terminating the etching process at said thermal expansion buffer layer to form streets on said backside metal layer; and
depositing at least one oxidation resistant layer to cover said backside metal layer and said streets on said backside metal layer.

10. The fabrication method according to claim 9, wherein said oxidation resistant layer is made of Ni, Au, Pd, Ni—Au alloys, Ni—Pd alloys, Pd—Au alloys, Ni—V alloys.
